(19) United States
(12) Patent Application Publication
(10) Pub. No.: US 2015/0145049 A1
(43) Pub. Date: May 28, 2015

(54) COMPLEMENTARY FET INJECTION FOR A FLOATING BODY CELL

(71) Applicant: Soitec, Crolles Cedex (FR)

(72) Inventors: Franz Hoffman, Munchen (DE); Richard Ferrant, Esquibien (FR); Carlos Mazure, Bernin (FR)

(21) Appl. No.: 14/396,665

(22) PCT Filed: May 8, 2013
(86) PCT No.: PCT/EP2013/059651

§ 371 Date: Oct. 23, 2014

(30) Foreign Application Priority Data
May 9, 2012 (FR) 1254236

(51) Int. Cl. H01L 27/108; H01L 27/092

(52) U.S. Cl. CPC H01L 27/10802; H01L 27/092
USPC 257/351

(57) ABSTRACT

The present invention relates to a floating body memory cell comprising: a first MOS transistor and a second MOS transistor, wherein at least the second MOS transistor has a floating body; and wherein the first and second MOS transistors are configured such that charges can be moved to/from the floating body of the second MOS transistor via the first MOS transistor.

### CROSS-REFERENCE TO RELATED APPLICATIONS

This application is a national phase entry under 35 U.S.C. §371 of International Patent Application PCT/EP2013/059651, filed May 8, 2013, designating the United States of America and published in English as International Patent Publication WO 2013/167691 A1 on Nov. 14, 2013, which claims the benefit under Article 8 of the Patent Cooperation Treaty and under 35 U.S.C. §119(e) to French Patent Application Serial No. 1254236, filed May 9, 2012, the disclosure of each of which is hereby incorporated herein in its entirety by this reference.

### TECHNICAL FIELD

The present invention relates to a semiconductor device for storing data. More specifically, it is related to a floating body-based memory cell.

### BACKGROUND

Memory devices are used in virtually every integrated circuit for various purposes, such as, for holding the variable and/or results of a computation or for storing input data. Depending on the application, the number of memory cells used can vary from some bits to several gigabytes. Therefore, in order to reduce costs, it is important to provide memory architectures that can be realized by using the least possible amount of silicon area. In this respect, one known approach consists in the implementation of memory cells relying on the floating body effect.

In particular, floating body-based memory devices use the floating body effect of a floating body transistor in order to store data within the transistor itself. More specifically, by changing the amount of charges stored within the electrically insulated body of a transistor, also known as floating body transistor, it is possible to change the threshold voltage of the same transistor. Applying a fixed gate voltage, the current through the transistor changes if there are charges in the body or not. Since the threshold voltage is a function of the charges stored in the body, the value stored by changing the amount of charges in the floating body of the device can be retrieved by reading the output current of the same device.

Floating body-based memories are known, for instance, from non-patent document “A Novel Low-Voltage Biasing Scheme for Double Gate FBC,” Z. Lu et al., Electron Devices Meeting (IEDM), 2010 IEEE International.

The conventional approach has the disadvantage that charges stored within the floating body transistor usually have to be created via a complex generation method, such as gate-induced drain leakage (Gidl), via a thyristor, via a hot carrier approach, or impact ionization method. Such complex generation methods usually require complex architectures and are not particularly efficient for the generation of charges. Also, these methods of generation can degrade the transistor by production of interface states.

### BRIEF SUMMARY

Therefore, it is an object of the invention to provide a floating body-based memory cell with a simple architecture. Further objects of the invention are to provide the memory cell with a design that ensures reliability, and/or small silicon area, and/or a design that can operate with low voltage power supplies.

In particular, an embodiment of the present invention can relate to a floating body memory cell comprising: a first MOS transistor and a second MOS transistor, wherein at least the second MOS transistor has a floating body, wherein the first and second MOS transistors are configured such that charges can be moved to/from the floating body of the second MOS transistor via the first MOS transistor.

This provides the beneficial advantage that a compact structure and a simple architecture is realized for the floating body memory cell. Moreover, the floating body memory cell can be operated with low voltage power supplies, thereby ensuring reliability.

In further advantageous embodiments, the floating body of the second MOS transistor can be connected to the drain or source of the first MOS transistor.

This provides the beneficial advantage that the architecture is further reduced and simplified and control of the charges within the floating body of the second MOS transistor is more effective.

In further advantageous embodiments, charges can be moved to/from the floating body of the second MOS transistor by electrostatic attraction to voltages applied to the drain and/or source and/or gate of the first and/or second MOS transistor.

This provides the beneficial advantage that complex charge generation methods are not needed and charges can be quickly and/or reliably moved to/from the floating body of the second MOS transistor.

In further advantageous embodiments, the second transistor can be set into inversion mode during the writing operation.

Setting the second transistor into inversion mode, respective to the stored charges being electrons or holes, provides the beneficial advantage that the number of charges in the floating body of the second MOS transistor is increased.

In further advantageous embodiments, at least the second MOS transistor can be a multi-gate transistor with at least a first and a second gate, and the second gate can be used to attract charges toward the bottom of the floating body of the second MOS transistor.

This provides the beneficial advantage that the number of charges in the floating body of the second MOS transistor is increased. Moreover, this increases reliability by moving the charges toward the insulating layer separating the floating body from the second gate.

In further advantageous embodiments, one of the first or second MOS transistors can be a pMOS and the other one of the first or second MOS transistors can be an nMOS.

This provides the beneficial advantage that the floating body memory cell can be realized with standard CMOS technology.

In further advantageous embodiments, during writing of the floating body memory cell writing, current can flow through the first and second transistors, while during reading of the floating body memory cell, a reading current can flow only through the second transistor.

This provides the beneficial advantage that the reading current does not have to flow through the first transistor, thereby reducing reading time and increasing precision of the read current value, as well as simplifying the control operation of the floating body memory cell. Additionally, since the reading and writing operations are separated, as writing of 1 or 0 is mainly done by the first transistor, while reading is done only by the second transistor, higher reliability can be achieved.

Additionally, an embodiment of the present invention can relate to an integrated circuit comprising a plurality of floating body memory cells in accordance with any of the previous claims.

This provides the beneficial advantage that an integrated circuit having a small area dedicated to memory can be realized.

### BRIEF DESCRIPTION OF THE DRAWINGS

The invention will be described in more detail hereinafter by way of example, using advantageous embodiments and with reference to the drawings. The described embodiments are only possible configurations in which the individual features, however, as described above, may be implemented independently of each other or may be omitted. Equal elements illustrated in the drawings are provided with equal reference signs. Parts of the description relating to equal elements illustrated in the different drawings may be left out. In the drawings:

FIG. 1 schematically illustrates a floating body memory cell 1000 in accordance with an embodiment of the present invention;

FIGS. 2-6 schematically illustrate some of the manufacturing steps used for the realization of the floating body memory cell of FIG. 1, in accordance with an embodiment of the present invention;

FIGS. 7-10 schematically illustrate the operation of the floating body memory cell of FIG. 1; and

FIGS. 11 and 12 schematically illustrate a floating body memory cell 2000 in accordance with a further embodiment of the present invention.

### DETAILED DESCRIPTION

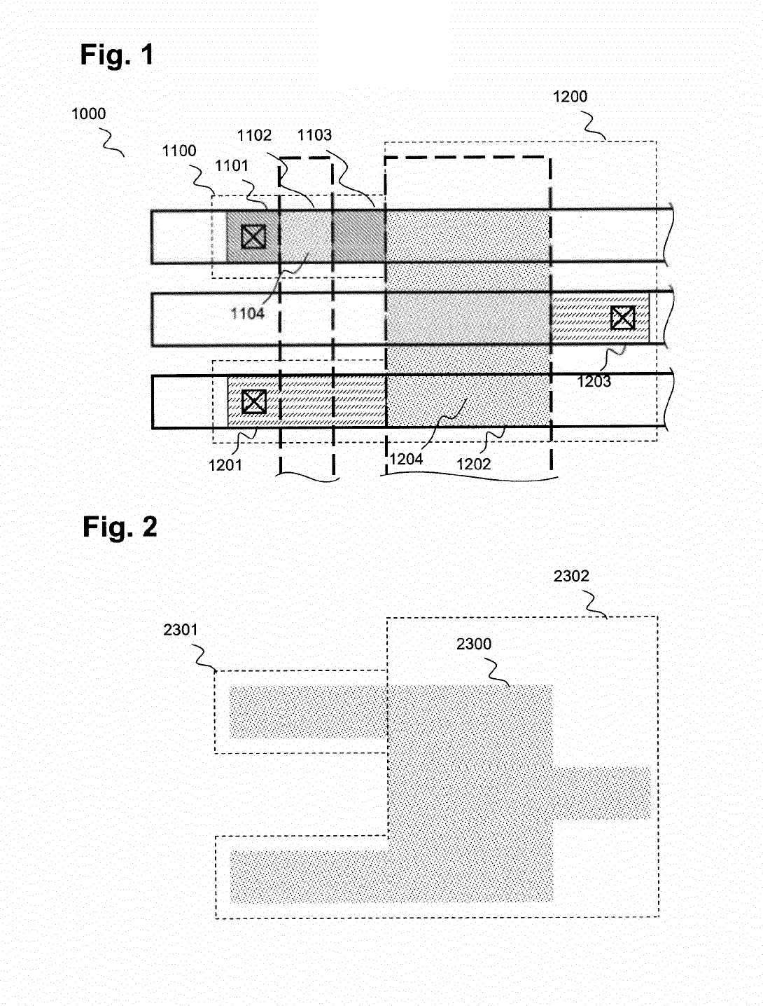

A floating body memory cell in accordance with an embodiment of the present invention will now be described with reference to FIG. 1.

As can be seen in FIG. 1, the floating body memory cell 1000 comprises a pMOS transistor 1100 and an nMOS transistor 1200. The pMOS transistor comprises a source 1101, a gate 1102 and a drain 1103. Similarly, the nMOS transistor comprises a source 1201, a gate 1202 and a drain 1203. Gate 1102 of the pMOS transistor 1100 and gate 1202 of nMOS transistor 1200 both overlap the respective body of the transistors, namely body 1104 of pMOS transistor 1100 and body 1204 of nMOS transistor 1200.

The two transistors 1100 and 1200 could be realized via silicon-on-insulator technology or via a FinFET technology or via any other technology that allows the realization of transistors having a floating body.

More specifically, the body 1204 of nMOS transistor 1200 is used in order to store a charge and acts as a floating body memory device. At the same time, pMOS transistor 1100 is used in order to inject and/or remove positive and/or negative charges from the body 1204 of nMOS transistor 1200. In particular, as can be seen in FIG. 1, the drain 1203 of pMOS transistor 1100 is connected to the body 1204 of nMOS transistor 1200. In this manner, by operating the pMOS transistor 1100, charges can be moved to and from the body 1204 of nMOS transistor 1200. Accordingly, the amount of electrical charges within body 1204 can be controlled via transistor 1100.

In the following, a schematic fabrication method of the floating body memory cell 1000 of FIG. 1 will be described with reference to FIGS. 2 through 6 in accordance with an embodiment of the present invention.

FIG. 2 schematically illustrates the active area 2300 of the floating body memory cell 1000. In particular, this layer represents the layer of a semiconductor material, which realizes the body, source and drain of the transistors. The semiconductor material could be, for instance, silicon, SiGe, etc. In the case of silicon-on-insulator (SOI) technology, the layer 2300 represents the silicon layer that is comprised between the top gate and the bottom gate of the transistors, also known as top silicon oxide layer and buried silicon oxide layer. In particular, the active area 2300 comprises a pMOS region 2301 in which pMOS transistor 1100 is realized and an nMOS region 2302 in which nMOS transistor 1200 is realized. In preferable embodiments, the active area may be doped by impurities, for instance, with a doping concentration smaller than 1e17 cm⁻³.

Although the active area 2300 is illustrated as having a specific shape, any shape can be employed that allows the construction of a floating body memory cell in which control of charges within the body of one of the transistors is achieved by means of the remaining transistor.

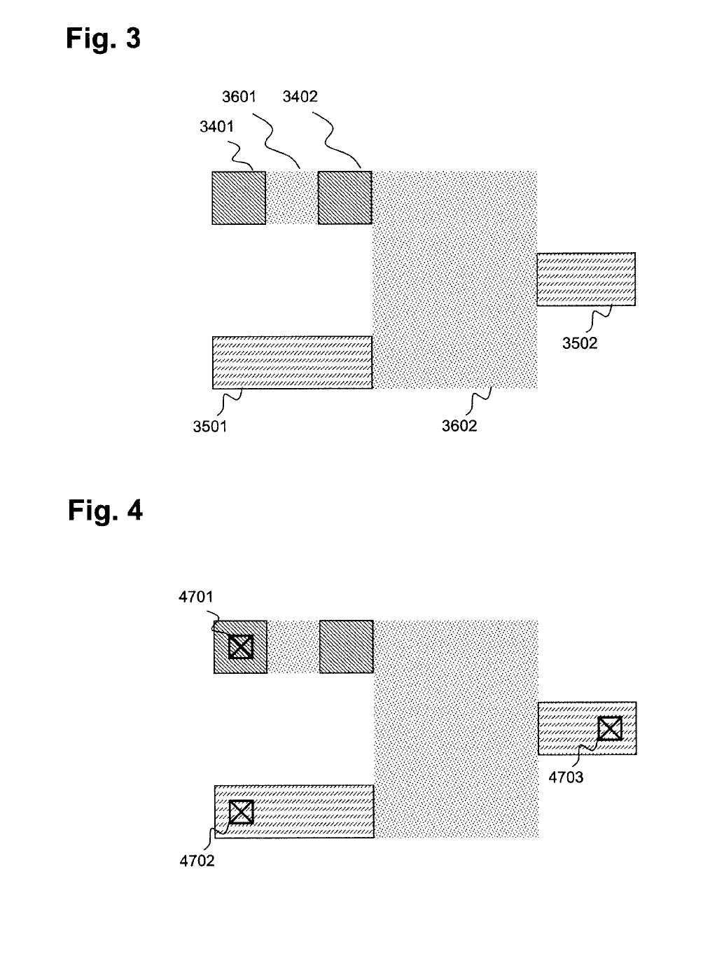

FIG. 3 schematically illustrates a subsequent fabrication step consisting in the realization of p+ and n+ doped regions.

In particular, within pMOS region 2301, p+ doped regions 3401 and 3402 are realized. Similarly, within nMOS region 2302, n+ doped regions 3501 and 3502 are realized. Specifically, p+ doped region 3401 acts as the source 1101 of pMOS transistor 1100 while p+ doped region 3402 acts as drain 1103 of pMOS transistor 1100. Similarly, n+ doped region 3501 acts as source 1201 of nMOS transistor 1200 while n+ doped region 3502 acts as drain 1203 of nMOS transistor 1200.

At the same time, for each of transistors 1100 and 1200, the region of active area 2300 between the respective doped regions acting as drain and source acts as the body of the respective transistor. Accordingly, region 3601 of active area 2300 acts as the body 1104 of pMOS transistor 1100. At the same time, region 3602 of active area 2300 acts as the body 1204 of nMOS transistor 1200.

It is to be noted that the sizes of the different regions are only schematically represented. In particular, it is advantageous for the size of the pMOS transistor 1100 to be smaller than the size of the nMOS transistor 1200 or, more specifically, the size of the pMOS transistor 1100 to be smaller than the size of the body 1204 of the nMOS transistor, since this allows the controlling pMOS transistor to occupy a small area and the memory nMOS transistor to contain a sufficient amount of charges. However, the present invention is not limited thereto and the relative dimensions of the two transistors could be of any value.

Similarly, the sizes of regions 3401, 3501 and 3502 are illustrated as being different with respect to each other. However, the present invention is not limited thereto. For instance, the size of p+ doped region 3401 could correspond to the size of n+ doped region 3501 and/or to the size of n+ doped region 3502. In particular, each of those regions only needs to be as large as necessary to allow a connection to be realized. In addition to that, any further advantageous shapes, such as the one illustrated in FIG. 3, can also be implemented.

FIG. 4 schematically illustrates a further manufacturing step for the floating body memory cell 1000. In particular, FIG. 4 illustrates the realization of contacts 4701, 4702 and 4703. Specifically, contact 4701 provides access to the p+ doped region 3401, contact 4702 provides access to the n+ doped region 3501, and contact 4703 provides access to the n+ doped region 3502. At the same time, p+ doped region 3402 does not require a contact since this region is used to contact the pMOS transistor 1100 with the body 1204 of nMOS transistor 1200. Accordingly, a connection to the rest of the circuit can be avoided. In particular, this can be advantageous since it may allow the size of p+ doped region 3402 to be smaller than, for instance, the size of p+ doped region 3401.

Contacts 4701-4703 are illustrated in the same manner. However, this does not imply that they are used to connect to the same level of metallization. In particular, each of the contacts 4701-4703 could connect the respective doped region to any metallization level of the floating body memory cell 1000.

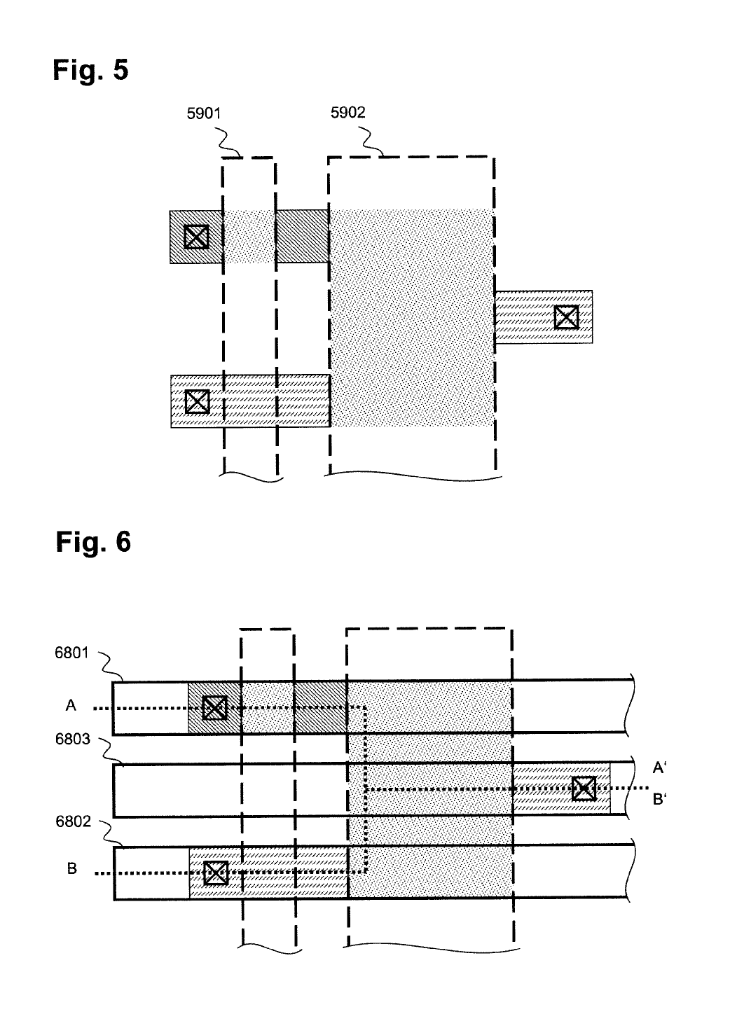

FIG. 5 schematically illustrates a further manufacturing step of the floating body memory cell 1000. In particular, in FIG. 5, vertical connections 5901 and 5902 are realized. Connection 5901 acts as a gate terminal for pMOS transistor 1100. Similarly, connection 5902 acts as a gate terminal for nMOS transistor 1200. The connections could each be on any metallization level of the floating body memory cell 1000. For ease of description, they will be considered as being on the same metallization level. However, the present invention is not limited thereto.

As can be seen, connection 5901 also overlaps with n+ doped region 3501. In this configuration, the doping of n+ doped region 3501 can be chosen such that the operation of connection 5901 does not impact the operation of nMOS transistor 1200. Alternatively, the connection 5901 can be shaped so as not to overlap with n+ doped region 3501 and/or the shape of n+ doped region 3501 can be made smaller, such as the one of region 3402, so as not to overlap with connection 5901. The advantage of using an n+ doped region 3501 shaped substantially as a combination of regions 3401, 3402 and 3601 consists in the fact that the pitch of the floating body memory cell 1000 is not increased, since the pitch is dictated by the combined length of regions 3401, 3402 and 3601, while, at the same time, the pitch is maintained at a minimum since the region 3402 not having a contact can be minimized, and contact 4702 can be placed to the left of connection 5901, in the space that is already required by contact 4701.

In logic terms, connection 5901 can be used as a word line write connection in order to set the floating body memory cell 1000 into a charged mode, while connection 5902 can be used as a word line read connection in order to set the floating body memory cell 1000 into a read mode.

As can be seen, thanks to the respective placement of the connections, the connections 5901 and 5902 can be realized in a substantially parallel manner and, therefore, on the same metallization level. Additionally, this provides the possibility of realizing several floating body memory cells 1000 next to each other, by simply elongating the connections 5901 and 5902.

FIG. 6 schematically illustrates a further manufacturing step of the floating body memory cell 1000. Specifically, in FIG. 6, three horizontal connections 6801-6803 are realized. The connections could each be on any metallization level of the floating body memory cell 1000. For ease of description, they will be considered as being on the same metallization level. However, the present invention is not limited thereto.

In particular, connection 6801 is used to provide a connection to contact 4701 and, therefore, to source 1101 of pMOS transistor 1100. Similarly, connection 6802 is used to provide a connection to contact 4702 and, therefore, to source 1201 of nMOS transistor 1200. Finally, connection 6803 is used in order to provide a connection to contact 4703 and, therefore, to drain 1203 of nMOS transistor 1200. As can be seen, thanks to the respective placement of the three contacts and the three respective connections, the three connections 6801-6803 can be realized in a substantially parallel manner and, therefore, on the same metallization level. Additionally, this provides the possibility of realizing several floating body memory cells 1000 next to each other by simply elongating the connections 6801-6803.

In logic terms, connection 6801 can be used as a bit line write connection so as to set the value written into floating body memory cell 1000. Connection 6802 can be used as a source line for the floating body memory cell 1000, providing a current path during reading mode. Finally, connection 6803 can be used as a bit line read connection used to read the value stored into the floating body memory cell 1000.

Although the step of FIG. 3 consisting in the realization of the doped regions is described above as being carried out before the realization of the gates of the transistors described with reference to FIG. 5, the present invention is not limited thereto and this step could be carried out after the realization of the gates. Even more generally, the order of any of the steps described above can be changed so as to accommodate different manufacturing processes.

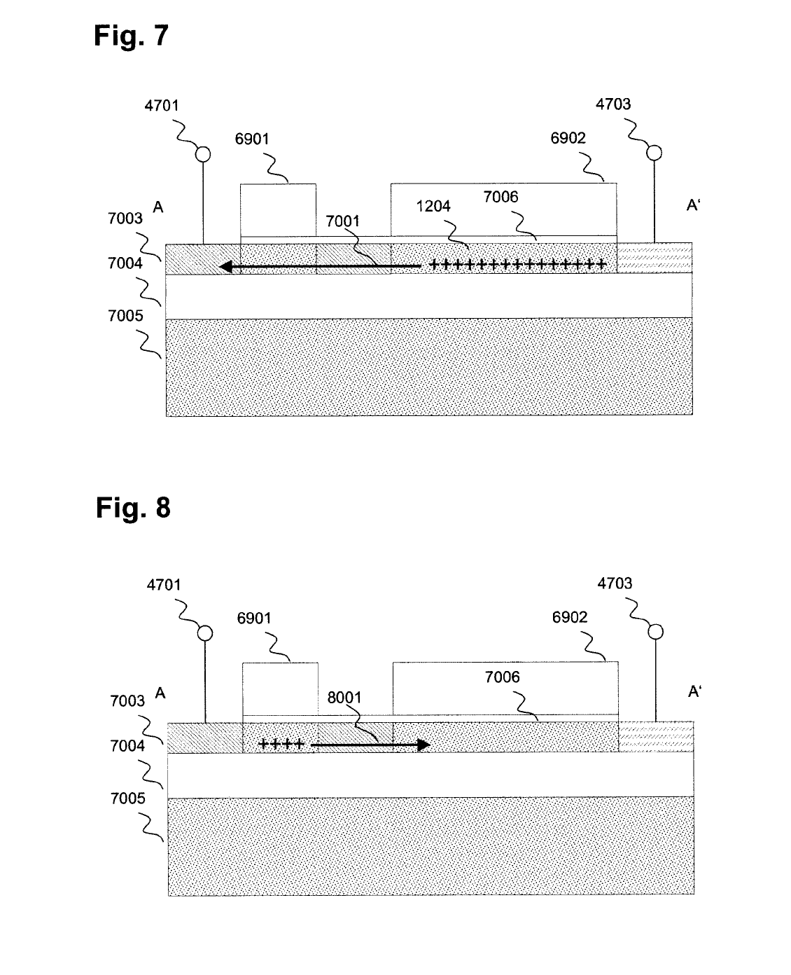

FIG. 7 schematically illustrates the vertical layers 7003-7006 realizing the floating body memory cell 1000. In particular, FIG. 7 is a cross-sectional view taken along dotted line A-A′ of FIG. 6.

Floating body memory cell 1000 comprises a first semiconductor layer 7003, a first insulation layer 7006, a second semiconductor layer 7005 and a second insulation layer 7004. As can be seen in FIG. 7, the first semiconductor layer 7003 is placed between the first and second insulation layers, while the second semiconductor layer 7005 is placed below the second insulation layer 7004.

Thanks to this approach, the first semiconductor layer 7003 can be used in order to realize the active area 2300 of FIG. 2. Additionally, the second semiconductor layer 7005 can be used as a back gate for the transistors 1100 and 1200, as will be explained below.

Although this embodiment is specifically related to an SOI architecture, the invention can also be realized with FinFets or any other technology that allows at least the body of transistor 1200 to be floating.

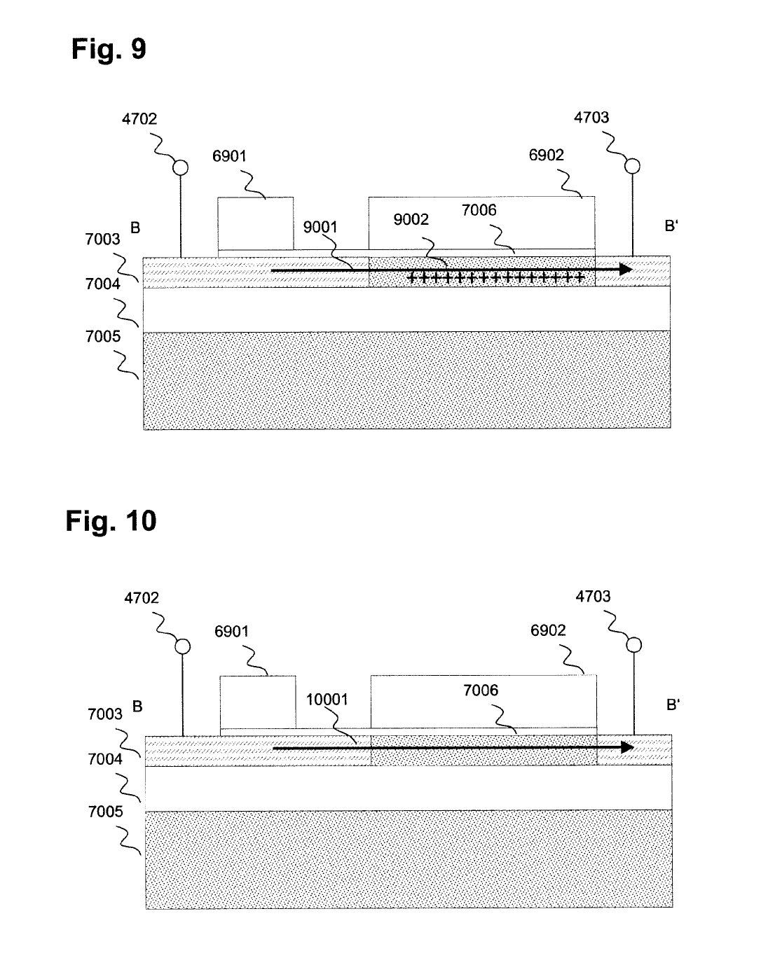

The operation of floating body memory cell 1000 will now be described with reference FIGS. 7 through 10. With reference to the cut lines A-A′ and B-B′ of FIG. 6, FIGS. 7 and 8 are taken along line A-A′, while FIGS. 9 and 10 are taken along line B-B′.

FIG. 7 schematically illustrates the operation of floating body memory cell 1000 during the writing of a logical value of 1. In particular, by applying a negative voltage to the gate 1102 of pMOS transistor 1100, that is, connection 6901, the pMOS transistor 1100 is turned on. At the same time, by applying a negative voltage to the contact 4701, positive charges from the body 1204 of nMOS transistor 1200 are drawn away from the body 1202 of nMOS transistor 1200, as illustrated by arrow 7001. In this manner, the body 1204 contains no charges, thereby storing a value of 1.

In addition, the gate 1202 of nMOS transistor 1200, that is, connection 6902, can also be set at a negative value so as to put transistor 1200 into inversion mode for a pMOS transistor. Moreover, connections 4703 can be set to a ground value, or to any absolute value higher than the voltage at contact 4701.

Here, the terms negative and positive are intended as “negative enough” and “positive enough” to achieve the above-described effects. For instance, contact 4701 could be set at a voltage in the range of −0.5V to −3V, preferably −1V. Moreover, the connection 6901 could be set at a voltage in the range of −1V to −4V, preferably −1V. Moreover, the connection 6902 could be set at a voltage in the range of 0V to −3V, preferably −1V. Moreover, contact 4703 could be set at a voltage in the range of 0V to −3V, preferably 0V. Applying a negative voltage, in this case the node 4703 is in reverse biasing, so the positive charges will flow to 4703.

The advantage of using the same set of voltage levels for connections 4701, and/or 6901, and/or 6902, and/or 4703 consists in the fact that the driving circuitry, as well as the respective I/O circuitry, can be simplified.

FIG. 8 schematically illustrates the operation of the floating body memory cell 1000 during the writing of a logical value of 0. In particular, the figure is taken along the same line A-A′ as for FIG. 7. However, some of the various voltages applied to the plurality of connections are different.

In particular, connection 4701 can be set to a ground voltage. In this manner, the positive charges flow through pMOS transistor 1100 to the body 1204 of nMOS transistor 1200, as indicated by arrow 8001. In this case connections 6901 and 6902 can be set at a negative voltage.

In addition, the charge movements could be improved by, for instance, setting the gate voltage of nMOS transistor 1200 at a more negative voltage than the gate voltage of pMOS transistor 1100. This could be achieved by setting connection 6902 at a lower voltage than the negative voltage of connection 6901. Alternatively, or in addition, this could also be achieved by setting the value of connection 4703 to a lower value with respect to the voltage value of connection 4701.

In this manner, a value of 0 is recorded within the body 1204 of nMOS transistor 1200; that is, the floating body of the transistor 1200 will be charged.

FIG. 9 schematically illustrates the reading operation of floating body memory cell 1000 when the floating body memory cell 1000 stores a value of 0, following the operation described with reference to FIG. 7. In particular, FIG. 9 is taken along line B-B′ of FIG. 6.

When the gate voltage of gate 1202 of nMOS transistor 1200 is set at a positive voltage, the nMOS is conducting; that is, it is turned ON, and a current can flow through it. By setting the voltage of contact 4703 at a level higher than the voltage of contact 4702, a current flows through nMOS transistor 1200, as illustrated by arrow 9001.

The value of the current depends on the threshold voltage of nMOS transistor 1200, which, in turn, depends on the charges stored in body 1204. Accordingly, the positive charges 9002 stored in body 1204 will increase the source/body barrier and thus cause the threshold voltage to increase and the current 9001 to decrease. Conversely, as illustrated in FIG. 10, since there are no positive charges, the current 10001 will be higher than current 9001. In this manner, it is possible to read out the value stored within floating body memory cell 1000.

Additionally, the back gate of nMOS transistor 1200, realized by means of layer 7005, can be electrically connected as well. In particular, it can be set to a negative value in the range of −2V to −6V, depending on the thickness of the box 7004, in particular −2V, during reading and/or writing operations, in order to increase the amount of positive charges in the body 1204 of nMOS transistor 1200. Additionally, this provides the further advantage that the positive charges are attracted toward the bottom of the body 1204, which increases the total number of charges in the body 1204. Moreover, the negative back gate voltage forms a minimum in the electrical potential for the holes, so positive charges can accumulate in this so-formed valley.

Further, alternatively, or in addition, it is also possible to discharge the body 1204 of nMOS transistor 1200 by applying a zero voltage to the back gate and a negative voltage to connection 6901 for writing of a logical value of 1.

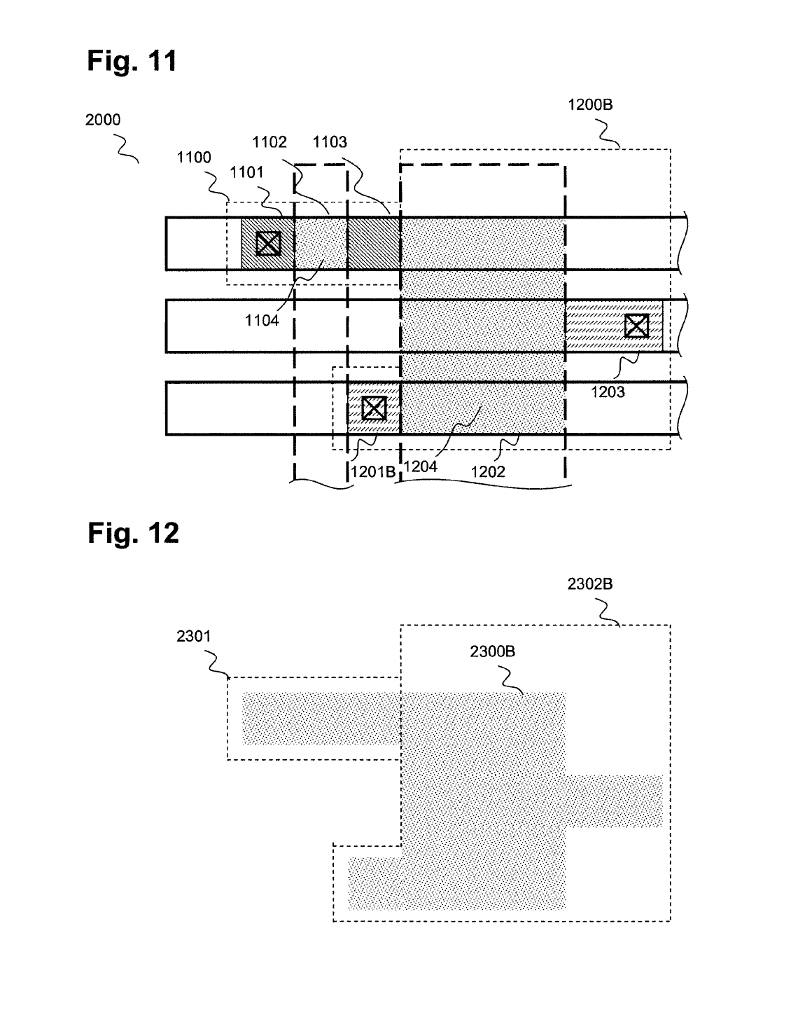

FIG. 11 illustrates a floating body memory cell 2000 in accordance with a further embodiment of the present invention. In particular, it differs from the floating body memory cell 1000 of FIG. 1 due to a different positioning of the source 1201B of nMOS transistor 1200B. More specifically, the source 1201B is arranged in between the vertical connections 5901 and 5902.

This also implies that the active area 2300B of the floating body memory cell 2000 is shaped differently from active area 2300 of the floating body memory cell 1000, particularly with reference to nMOS region 2302B in which nMOS transistor 1200B is realized. The respective placement of n+ doped region 3501 and contact 4702 follow the changes to the active area 2300B.

This provides the beneficial advantage that vertical connection 5901 does not overlap with the n+ doped region 3501, which broadens the doping requirements for the n+ doped region 3501, since its behavior is less influenced by connection 5901. Accordingly, the process flow could be simpler.

The floating body memory cell 100 is realized with such a shape that a plurality of such cells can be placed in a line and/or matrix arrangement. For instance, two floating body memory cells could be placed in a horizontal line, such that region 3502 is interleaved between regions 3501 and the pMOS transistor 1100. In this manner, the horizontal pitch of the two cells is minimized. Alternatively, or in addition, the two cells could be vertically placed one above the other. Still alternatively, or in addition, the horizontal and vertical combinations could be combined to realize a matrix placement.

Although in the previous embodiment the pMOS and nMOS transistors have been described as having a specific orientation for the drain and sources, the present invention is not limited thereto. Alternatively, or in addition, the drain/source of any of pMOS transistor 1100 and nMOS transistor 1200 could be oriented differently. For instance, region 3401 could act as the drain 1103 of pMOS transistor 1100 while region 3402 could act as source 1101 of pMOS transistor 1100.

Moreover, although in the previous embodiments an nMOS transistor has been used in order to store charges, this is an example only and the present invention could be realized by implementing transistor 1100 as an nMOS and transistor 1200 as a pMOS.

Moreover, although in the previous embodiments the charges moved are described as being the positive charges, the present invention is not limited thereto and it will be clear to the person skilled in the art how a similar effect can be achieved by moving negative charges or both negative and positive charges at the same time.

1. A floating body memory cell, comprising:
a first MOS transistor and a second MOS transistor, wherein at least the second MOS transistor has a floating body and
wherein the first MOS transistor and the second MOS transistor are configured such that charges can be moved to and/or from the floating body of the second MOS transistor via the first MOS transistor.

2. The floating body memory cell of claim 1, wherein the floating body of the second MOS transistor is connected to a drain or a source of the first MOS transistor.

3. The floating body memory cell of claim 1, wherein charges are moved to and/or from the floating body of the second MOS transistor by electrostatic attraction to voltages applied to at least one of a source, a gate, and a drain of the first MOS transistor and/or the second MOS transistor.

4. The floating body memory cell of claim 1, wherein the second MOS transistor is set into an inversion mode during a writing operation of the floating body memory cell.

5. The floating body memory cell of claim 1, wherein:
at least the second MOS transistor is a multi-gate transistor including at least a first gate and a second gate; and
the second gate is located and configured to attract charges toward a bottom of the floating body of the second MOS transistor.

6. The floating body memory cell of claim 1, wherein one of the first MOS transistor and the second MOS transistor is a pMOS transistor and another of the first MOS transistor and the second MOS transistor is an nMOS transistor.

7. The floating body memory cell of claim 1, wherein a writing current flows through the first MOS transistor and the second MOS transistor during a writing operation of the floating body memory cell, and wherein a reading current flows only through the second MOS transistor during a reading operation of the floating body memory cell.

8. (canceled)

9. The floating body memory cell of claim 2, wherein charges are moved to and/or from the floating body of the second MOS transistor by electrostatic attraction to voltages applied to at least one of a source, a gate, and a drain of the first MOS transistor and/or the second MOS transistor.

10. The floating body memory cell of claim 9, wherein one of the first MOS transistor and the second MOS transistor is a pMOS transistor and another of the first MOS transistor and the second MOS transistor is an nMOS transistor.

11. An integrated circuit, comprising:
at least one floating body memory cell including:
a first MOS transistor having a first source, a first drain, and a first gate; and
a second MOS transistor having a second source, a second drain, a second gate, and a floating body, the floating body of the second MOS transistor being connected to the first MOS transistor such that the first MOS transistor can be used to move charges to and from the floating body of the second MOS transistor.

12. The integrated circuit of claim 11, wherein the at least one floating body memory cell comprises a plurality of floating body memory cells.

13. The integrated circuit of claim 11, wherein the drain of the first MOS transistor is connected to the floating body of the second MOS transistor.

14. The integrated circuit of claim 11, wherein the floating body memory cell has a silicon-on-insulator (SOI) architecture.

15. The integrated circuit of claim 11, wherein each of the first source, the first drain, and the first gate of the first MOS transistor, as well as each of the second source, the second drain, the second gate, and the floating body of the second MOS transistor, comprise regions of a common layer of semiconductor material.

16. The integrated circuit of claim 11, wherein a size of the first MOS transistor is smaller than a size of the second MOS transistor.

17. The integrated circuit of claim 11, wherein charges are moved to and/or from the floating body of the second MOS transistor by electrostatic attraction to voltages applied to at least one of a source, a gate, and a drain of the first MOS transistor and/or the second MOS transistor.

18. The integrated circuit of claim 11, wherein:
at least the second MOS transistor is a multi-gate transistor including at least a first gate and a second gate; and
the second gate is located and configured to attract charges toward a bottom of the floating body of the second MOS transistor.

19. The integrated circuit of claim 11, wherein one of the first MOS transistor and the second MOS transistor is a pMOS transistor and another of the first MOS transistor and the second MOS transistor is an nMOS transistor.

20. The integrated circuit of claim 11, wherein the at least one floating body memory cell is configured such that a writing current flows through the first MOS transistor and the second MOS transistor during a writing operation of the at least one floating body memory cell, and such that a reading current flows only through the second MOS transistor during a reading operation of the at least one floating body memory cell.
